(19) United States
(12) Patent Application Publication
(10) Pub. No.: US 2026/0147026 A1
(43) Pub. Date: May 28, 2026

(54) METHOD FOR MEASURING AN IMPEDANCE OF AN ACTIVE DEVICE UNDER TEST AND OSCILLOSCOPE FOR MEASURING AN IMPEDANCE OF AN ACTIVE DEVICE UNDER TEST

(71) Applicant: Rohde & Schwarz GmbH & Co. KG, Muenchen (DE)

(72) Inventors: Benedikt LIPPERT, Muenchen (DE); Thomas KUHWALD, Muenchen (DE); Alessandro CAPPELLETTI, Muenchen (DE)

(21) Appl. No.: 18/960,575

(22) Filed: Nov. 26, 2024

(51) Int. Cl. G01R 27/26

(52) U.S. Cl. CPC G01R 27/26

(57) ABSTRACT

A method for measuring an impedance of an active device under test is described. The method includes: transmitting a test signal to an active device under test; receiving a signal from the active device under test, wherein the signal includes a reflection of the transmitted test signal; and performing a clock data recovery on the signal received from the active device under test.

### FIELD OF THE DISCLOSURE

Embodiments of the present disclosure relate to a method and an oscilloscope for measuring an impedance of an active device under test.

### BACKGROUND

Compliance testing of digital interfaces, e.g. HDMI, requires measuring an impedance of a transmitter and/or receiver. Such a measurement can be performed via time-domain reflectometry (TDR). In TDR, a test signal is transmitted to a device under test (DUT), for instance a transmitter or a receiver. A signal comprising reflections of the test signal from the DUT is received and analyzed. In the case of an active (actively transmitting) DUT, a data signal transmitted by the DUT is also present in the received signal and overlaps with the test signal. Accordingly, the data signal impedes a correct analysis of the received signal.

Sometimes it is required to measure an impedance of an active DUT, for example in HDMI compliance testing. Since an active DUT transmits a data signal that would typically disturb the impedance measurement, such measurements are currently performed with a vector network analyzer (VNA). A resolution bandwidth of the VNA is set to a small value such that the data signal disturbs the measurement as little as possible.

However, VNAs are expensive test and/or measurement instruments and using them in such measurements is associated with high wiring efforts.

Accordingly, there is a need for measuring an impedance of an active DUT in a more (cost-)efficient manner.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

The present disclosure provides examples of a method for measuring an impedance of an active device under test. In an embodiment, the method comprises: transmitting a test signal to an active device under test; receiving a signal from the active device under test, wherein the signal comprises a reflection of the transmitted test signal; and performing a clock data recovery on the signal received from the active device under test.

By performing the clock data recovery (CDR), timing information regarding the test signal can be derived from the received signal irrespective of any unwanted signals potentially introduced by the active device under test (DUT), e.g. a signal actively transmitted by the DUT. In an embodiment, an active device under test is a device under test that actively transmits a signal. The method thus allows measuring the impedance of the active DUT without requiring a vector network analyzer (VNA), thereby ensuring a cost-efficient possibility to measure the impedance of the active DUT. Instead, an oscilloscope is sufficient for measuring the impedance of the active DUT. In an embodiment, VNAs are typically more expensive compared to oscilloscopes. In addition, using a VNA for measuring an impedance of an active DUT is associated with a high wiring effort, for example compared to using an oscilloscope. Hence, the method reduces complexity, effort, and costs substantially, as the method can be performed by using an oscilloscope.

Moreover, when performing measurements on DUTs having a digital interface, typically a real-time oscilloscope is used. For example, an eye pattern of a data signal is analyzed, e.g. the openings of the eyes. The method allows using the real-time oscilloscope also for measuring the impedance of the active DUT without requiring further test and/or measurement equipment. Comprehensive testing of the DUT can thus be performed in a particularly efficient manner.

In an embodiment, the CDR may be based on a phase-locked loop (PLL), especially a narrow-band PLL. For example, the implemented CDR can be considered a feed-forward CDR.

An aspect provides, for example, that a trigger may be applied to the received signal based on a result of the clock data recovery and signal sections may be acquired upon trigger events. Hence, the triggering and the ensuing signal section acquisition can have a stable temporal relationship with timing information of the test signal (which was determined by the CDR). In other words, the CDR is used as a trigger source for triggering signal acquisitions.

In an embodiment, the signal sections acquired may be averaged. Thus, an unwanted signal overlapping with the reflection of the test signal can be removed from the received signal, as the reflection of the test signal and the unwanted signal are not correlated with each other. For example, averaging can be performed by adding a number of n acquired signal sections and dividing resulting amplitude values by n. As one specific example, n may be approximately 10000.

In an embodiment, a reflected test signal may be extracted from the received signal based on the averaging of the signal sections acquired. Since the averaging can remove unwanted signals from the received signal (as mentioned above), only the reflected test signal remains and can thus be extracted.

In an embodiment, an impedance of the device under test may be determined based on the reflected test signal and the transmitted test signal. Because the reflected signal is extracted from the received signal, the impedance of the DUT can be determined in an accurate manner. Moreover, the determination of the impedance is not obstructed by an unwanted signal, since it has been removed from the received signal when extracting the reflected signal. For example, the scattering parameter S11 of the active DUT may be determined.

In an embodiment, the received signal may comprise, in addition to the reflection of the transmitted test signal, a data signal transmitted by the active device under test. As mentioned above regarding unwanted signals, the data signal actively transmitted by the DUT can be removed from the received signal by averaging the acquired signal sections. Accordingly, a reflection of the transmitted test signal can be extracted from the signal that also comprises the data signal that was actively transmitted by the DUT in addition to reflecting the transmitted test signal.

For example, an output impedance of the active DUT can thus be determined. Especially, the impedance may be measured while the DUT is actively transmitting the data signal.

In an embodiment, the test signal may comprise a pulse signal. Hence, pulses of the transmitted test signal can be used together with corresponding pulses reflected from the active DUT to determine the impedance of the active DUT. The CDR may be configured such that it synchronizes with a known frequency of the test signal transmitted, for example a frequency of the pulses. In other words, the CDR may be configured to find pulses with a known frequency in the received signal.

In an embodiment, a frequency of the test signal may be different from a frequency of the data signal. The frequency difference can help in removing the data signal from the received signal comprising the reflection of the transmitted test signal. Typically, the test signal and the unwanted signal, e.g. the data signal, are not correlated. To further ensure a differentiation between the test signal and the data signal, a frequency of the test signal and/or of the data signal of the active DUT may be adapted, e.g. for providing a bigger difference.

In a typical case, the frequency of the test signal may be smaller than the frequency of the data signal. For example, the frequency of the test signal may be at least 20%, at least 40%, or at least 80% smaller than the frequency of the data signal. As one specific example, the frequency of the pulse signal may be approximately 10 MHz.

In an embodiment, the data signal may be DC free. In other words, the data signal can be at least substantially without DC bias. A DC-free data signal can be removed from a received signal by averaging acquired signal sections. This aids in extracting a reflected test signal from the received signal that also comprises the data signal.

In an embodiment, the data signal may be DC-balanced due its encoding algorithm. For example, the data signal may comply with the Transition-Minimized Differential Signaling (TMDS) standard.

In an embodiment, an edge trigger may be used for triggering on edges within the result of the clock data recovery. Thus, pulses of the test signal may be identified by the edge trigger.

In an embodiment, a trigger sequence may be used for triggering on edges within the result of the clock data recovery. As one option, the trigger sequence may comprise an A-trigger condition and a B-trigger condition. The trigger sequence may be set up for example such that triggering occurs if either of the conditions is fulfilled (A or B), both of the conditions are fulfilled (A and B), or only if condition B is fulfilled after condition A (A→B). The trigger sequence (or generally the edge trigger) can be configured to trigger only on rising edges or only on falling edges.

In an embodiment, the clock data recovery may detect eye centers of an eye pattern. A holdoff condition can be used for triggering on the first rising edge after an eye center of the eye pattern. The holdoff condition can enable triggering specifically on only the first edge after the eye center.

As mentioned above, the test signal may comprise a pulse signal. In an embodiment, the holdoff time may be set to half of a period of the pulse signal. Hence, further triggering can be prevented for half of a period of the pulse signal. More specifically, the holdoff time allows triggering on the first edge after an eye center (of the eye pattern) and avoiding further triggering for half of the period of the pulse signal.

The present disclosure further provides examples of an oscilloscope for measuring an impedance of an active device under test. Features and advantages of the method(s) described above apply analogously to the oscilloscope.

In an embodiment, the oscilloscope comprises an electronic circuit configured for transmitting a test signal to an active device under test and receiving a signal from the active device under test. The signal comprises a reflection of the transmitted test signal. The electronic circuit is further configured for performing a clock data recovery on the signal received from the active device under test.

In an embodiment, the electronic circuit may further be configured to apply a trigger to the received signal based on a result of the clock data recovery and to acquire signal sections upon trigger events.

In another embodiment, the electronic circuit may be configured to average the signal sections acquired. Further, the electronic circuit may be configured to extract a reflected test signal from the signal received based on the averaging of the signal sections acquired.

In an embodiment, the electronic circuit may be configured to determine an impedance of the device under test based on the reflected test signal and the transmitted test signal. Hence, an oscilloscope can be provided that is capable of determining an impedance of an active DUT without requiring additional expensive equipment. For example, no vector network analyzer is required when using the oscilloscope according to the present disclosure for determining the impedance of the active DUT.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 is a block diagram schematically illustrating a method for measuring an impedance of an active device under test according to an embodiment of the present disclosure;

FIG. 2 is a diagram schematically illustrating a test signal without reflections according to one aspect of the present disclosure;

FIG. 3 is a diagram schematically illustrating a test signal with overlapping reflections according to one aspect of the present disclosure;

FIG. 4 is a diagram schematically illustrating a section of a data signal according to one aspect of the present disclosure;

FIG. 5 is a diagram schematically illustrating a test signal overlapped by reflections and a data signal according to one aspect of the present disclosure;

FIG. 6 is a diagram schematically illustrating a received signal, recovered clock data, and trigger events according to one aspect of the present disclosure; and

FIG. 7 is a diagram schematically illustrating an example embodiment of an oscilloscope according to the present disclosure connected to an active device under test.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

FIG. 1 is a block diagram schematically illustrating an example of a method for measuring an impedance, which can be performed by an oscilloscope 8 shown in FIG. 7. In an embodiment, the oscilloscope 8 is enabled to measure the impedance of an active device under test (DUT) 10 to which the oscilloscope 8 is connected.

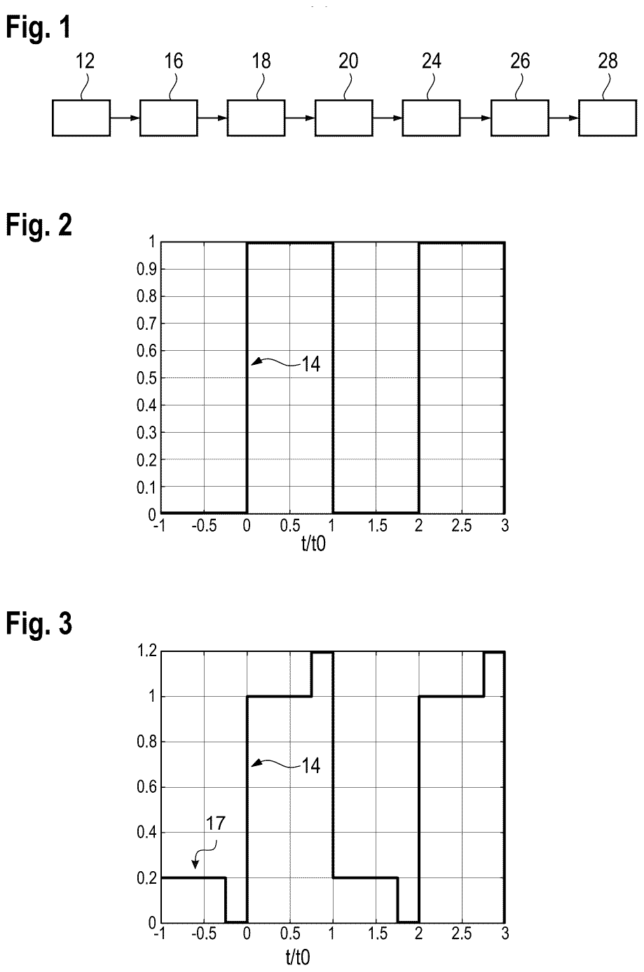

The method, which can be performed by the oscilloscope 8, comprises a first step 12 of transmitting a test signal 14, which is shown, for example, in FIG. 2, to the active device under test 10.

FIG. 2 is a diagram schematically illustrating a representative embodiment of the test signal 14. The test signal 14 is depicted as a function of time. Specifically, the horizontal axis (x-axis) indicates time relative to a pulse length t0 of the test signal 14. The vertical axis (y-axis) relates to a magnitude of the signal. In the depicted example, the test signal 14 is a pulse signal.

Further, the method comprises a second step 16 of receiving a signal from the active device under test 10, wherein the signal comprises at least a reflection of the transmitted test signal 14. In an embodiment, the reflection causes a signal that provides a deviation 17 from the transmitted test signal 14, as can be seen from the comparison of FIGS. 2 and 3.

In FIG. 3, the test signal 14 of FIG. 2 is schematically illustrated with overlapping reflections of the transmitted test signal 14, wherein the reflections originate from the active DUT 10 being passive, namely without actively transmitting a signal that might distort the reflection(s). The reflections distort the originally transmitted test signal 14 depicted in FIG. 2, which is obvious when comparing FIGS. 2 and 3.

In addition, the method comprises a third step 18 of performing a clock data recovery (CDR) on the signal received from the active device under test 10. Hence, timing information regarding the test signal 14 can be derived from the received signal by the clock data recovery.

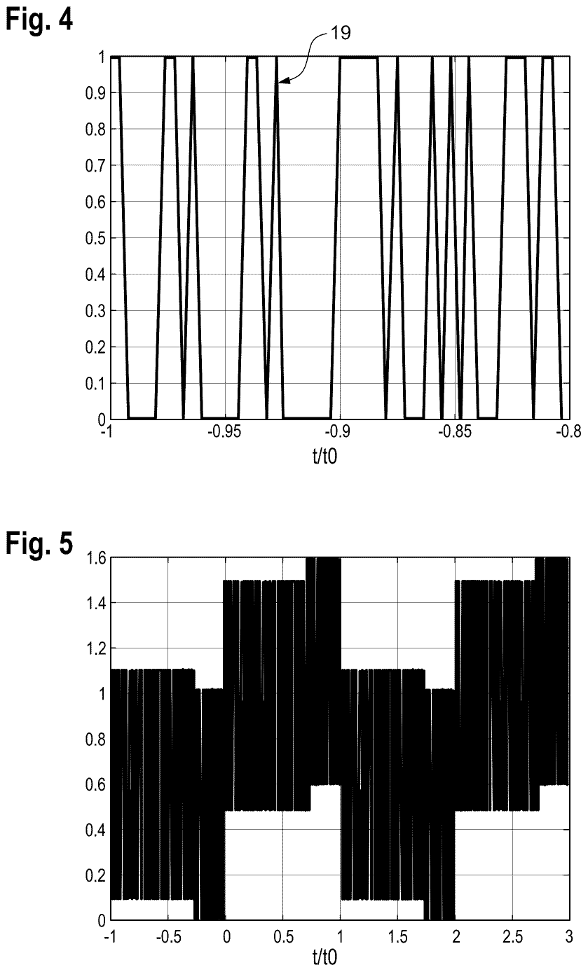

In an embodiment, the active device under test 10 however may transmit a data signal 19, for example a DC free data signal 19, a section of which is schematically illustrated in FIG. 4. Hence, the data signal 19 may overlap with the reflection of the transmitted test signal 14 in case of the measurement mentioned above provided that the active DUT 10 actively transmits the data signal 19 during the measurement.

FIG. 5 is an example of a diagram schematically illustrating the test signal 14 overlapped by reflections of the (passive) DUT 10 and the data signal 19 actively transmitted by the DUT 10. The combined effect of the overlapping reflection(s) (FIG. 3) and the overlapping data signal 19 (FIG. 4) can be seen from FIG. 5.

In the depicted example, a frequency of the transmitted test signal 14 is much smaller than a frequency of the overlapping data signal 19.

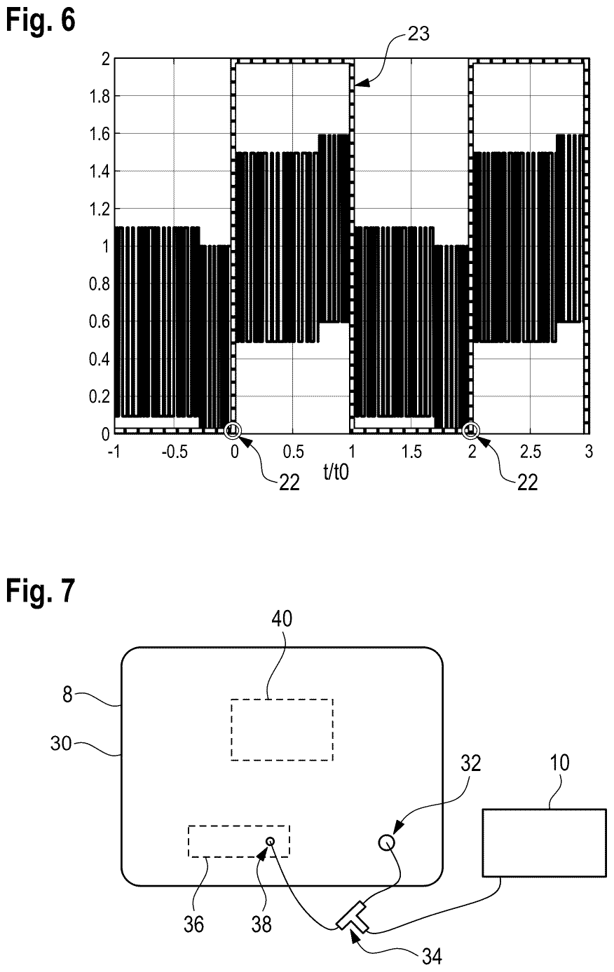

In an embodiment, the method also comprises a fourth step 20 of applying a trigger to the received signal based on a result of the clock data recovery. Hence, the timing information obtained from the clock data recovery is used for triggering. Upon trigger events 22, signal sections are acquired, an example of which is illustrated in FIG. 6 to which reference is made later in more detail.

Generally, different triggers may be applied, for instance an edge trigger that is used for triggering on edges within the result of the clock data recovery. Alternatively or additionally, a trigger sequence is used for triggering on edges within the result of the clock data recovery. As one option, the trigger sequence may comprise an A-trigger condition and/or a B-trigger condition, e.g. a so-called AB trigger.

In FIG. 6, the same overlap of the signals and the reflections as in FIG. 5 is shown, but in addition, recovered clock data 23 as well as the trigger events 22 are indicated.

Further, the method comprises, for example, a fifth step 24 of averaging the acquired signal sections. Thus, an unwanted signal, e.g. the data signal 19, overlapping with the reflection of the test signal 14 can be removed from the received signal, as the reflection of the test signal 14 and the unwanted signal, e.g. the data signal 19, are not correlated with each other.

In a sixth step 26, a reflected test signal is extracted from the received signal based on the averaging of the signal sections acquired. Since the averaging can remove the unwanted signal like the data signal 19 actively transmitted by the active DUT 10 from the received signal, as mentioned above in the fifth step 24, only the reflected test signal remains, which can thus be extracted.

The method may also comprise a seventh step 28 of determining an impedance of the device under test 10 based on the reflected test signal and the transmitted test signal 14. Since the reflected test signal can be isolated and extracted, it is possible to determine the impedance of the active device under test 10 even though the device under test 10 actively transmits a signal during the measurement, for instance the data signal 19 having an impact on the signal received.

FIG. 7 is a diagram schematically illustrating an example embodiment of an oscilloscope 8 connected to the active device under test 10. The oscilloscope 8 may be a real-time oscilloscope 30. In the depicted example, an input connector 32 of the oscilloscope 8 is connected to the active device under test 10 via a combiner 34.

In an embodiment, the oscilloscope 8 comprises a pulse source 36 with a pulse source connector 38. The pulse source connector 38 is also connected to the active device under test 10 via the combiner 34. Hence, a pulse signal can be transmitted to the active device under test 10 as the test signal 14. Accordingly, the oscilloscope 8 can function as a time-domain reflectometer.

In an embodiment, the oscilloscope 8 comprises an electronic circuit 40. The electronic circuit 40 may be configured to perform one or more of (or all of) the methods for measuring the impedance of the active device under test 10 as described herein, for example as described above with reference to FIGS. 1-6.

In addition to the aspects discussed above, the clock data recovery also detects, for example, eye centers of an eye pattern of the signal received. A holdoff condition can be used for triggering on the first rising edge after an eye center of the eye pattern.

As shown above, the test signal 14 comprises a pulse signal. A holdoff time can be set to half of a period of the pulse signal.

Generally, example of the present disclosure allows for measuring an impedance of an active DUT in a more (cost-)efficient manner.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the oscilloscope 8, the DUT 10, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method for measuring an impedance of an active device under test, the method comprising:
transmitting a test signal to an active device under test;
receiving a signal from the active device under test, wherein the signal comprises a reflection of the transmitted test signal; and
performing a clock data recovery on the signal received from the active device under test.

2. The method according to claim 1, wherein a trigger is applied to the received signal based on a result of the clock data recovery and wherein signal sections are acquired upon trigger events.

3. The method according to claim 2, wherein the signal sections acquired are averaged.

4. The method according to claim 3, wherein a reflected test signal is extracted from the received signal based on the averaging of the signal sections acquired.

5. The method according to claim 4, wherein an impedance of the device under test is determined based on the reflected test signal and the transmitted test signal.

6. The method according to claim 1, wherein the received signal comprises, in addition to the reflection of the transmitted test signal, a data signal transmitted by the active device under test.

7. The method according to claim 1, wherein the test signal comprises a pulse signal.

8. The method according to claim 6, wherein a frequency of the test signal is different from a frequency of the data signal.

9. The method according to claim 8, wherein the frequency of the test signal is smaller than the frequency of the data signal.

10. The method according to claim 6, wherein the data signal is DC free.

11. The method according to claim 1, wherein an edge trigger is used for triggering on edges within the result of the clock data recovery.

12. The method according to claim 1, wherein a trigger sequence is used for triggering on edges within the result of the clock data recovery.

13. The method according to claim 1, wherein the clock data recovery detects eye centers of an eye pattern and wherein a holdoff condition is used for triggering on the first rising edge after an eye center of the eye pattern.

14. The method according to claim 13, wherein the test signal comprises a pulse signal and wherein a holdoff time is set to half of a period of the pulse signal.

15. An oscilloscope for measuring an impedance of an active device under test, the oscilloscope comprising: an electronic circuit configured for: transmitting a test signal to an active device under test, receiving a signal from the active device under test, wherein the signal comprises a reflection of the transmitted test signal, and performing a clock data recovery on the signal received from the active device under test.

16. The oscilloscope according to claim 15, wherein the electronic circuit is further configured to apply a trigger to the received signal based on a result of the clock data recovery and to acquire signal sections upon trigger events.

17. The oscilloscope according to claim 16, wherein the electronic circuit is further configured to average the signal sections acquired.

18. The oscilloscope according to claim 17, wherein the electronic circuit is further configured to extract a reflected test signal from the signal received based on the averaging of the signal sections acquired.

19. The oscilloscope according to claim 18, wherein the electronic circuit is further configured to determine an impedance of the device under test based on the reflected test signal and the transmitted test signal.
